(19) United States
(12) Patent Application Publication
(10) Pub. No.: US 2020/0343085 A1
(43) Pub. Date: Oct. 29, 2020

(54) Edge Shaping of Substrates

(71) Applicant: Infineon Technologies AG, Neubiberg (DE)

(72) Inventors: Nirdesh Ojha, Villach (AT); Roland Rupp, Lauf (DE); Francisco Javier Santos Rodriguez, Villach (AT)

(21) Appl. No.: 16/397,795

(22) Filed: Apr. 29, 2019

(51) Int. Cl. H01L 21/02; H01L 29/16; B23H 7/06; B23H 7/32; B23H 7/34; B23H 3/02

(52) U.S. Cl. CPC H01L 21/02021; H01L 29/1608; B23H 7/06; B23H 2500/20; B23H 7/34; B23H 3/02; B23H 7/32

(57) ABSTRACT

A method includes producing a bulk substrate and beveling an edge of the bulk substrate using an electrical discharge machining (EDM) process and/or an electrochemical discharge machining (ECDM) process.

### BACKGROUND

Bulk SiC wafers have a typical thickness of about 350 μm or thicker, and are provided with a beveled edge which circumscribes the perimeter of the wafer. For some types of SiC devices such as vertical devices, a bulk SiC wafer is too thick and must be thinned. However, the typical thickness of the beveled edge of a bulk SiC wafer is about 100 μm (microns). If the extent of thinning of a bulk SiC wafer carries into the beveled edge region of the bulk wafer, the shape of the beveled edge changes and the resulting thinned SiC wafer has sharp edges. A bulk SiC wafer thinned to a thickness which erodes part of the original beveled edge will have sharp edges which present several challenges for handling and lead to wafer breakage by hairline cracks.

Thus, there is a need for re-beveling of thinned SiC wafers to prevent sharp edges.

### SUMMARY

According to an embodiment of a method, the method comprises: producing a thinner substrate from a thicker bulk substrate; and processing an edge of the thinner substrate using an electrical discharge machining (EDM) process and/or an electrochemical discharge machining (ECDM) process.

The thicker bulk substrate may be a semiconductor wafer, a glass substrate, a ceramic substrate, etc. In the case of a semiconductor wafer, the thinner wafer produced from the thicker wafer may be a device wafer which includes one or more activate and/or passive electrical devices.

The thinner substrate may be produced from the thicker bulk substrate by separating or cutting the thinner substrate from the bulk substrate, by thinning the backside of the bulk substrate, e.g. by grinding, etc.

The thicker bulk substrate may have a beveled edge prior to producing the thinner substrate from the thicker bulk substrate, and processing the edge of the thinner substrate using the EDM process and/or ECDM process may include processing the part of the beveled edge of the thicker bulk substrate retained by the thinner substrate using the EDM process and/or ECDM process.

Processing the part of the beveled edge of the thicker bulk substrate retained by the thinner substrate using the EDM process may comprise: covering the part of the beveled edge of the thicker bulk substrate retained by the thinner substrate with a dielectric liquid; applying voltage pulses between the tool electrode and the part of the beveled edge of the thicker bulk substrate retained by the thinner substrate; and moving the tool electrode and/or the thinner substrate in the dielectric liquid to maintain a plasma between the tool electrode and the thinner substrate. The tool electrode may be tilted along one or more different axes during the EDM process to change an angle of the beveled edge retained of the thicker bulk substrate by the thinner substrate and/or to change the shape of the beveled edge of the thicker bulk substrate retained by the thinner substrate. Alternatively, the tool electrode may be moved only in a vertical direction to maintain the plasma and so that an angle of the beveled edge of the thicker bulk substrate retained by the thinner substrate remains unchanged by the EDM process.

Processing the part of the beveled edge of the thicker bulk substrate retained by the thinner substrate using the ECDM process may comprise: covering the part of the beveled edge of the thicker bulk substrate retained by the thinner substrate with a low-conductive electrolyte; and applying voltage pulses between a tool electrode and the part of the beveled edge of the thicker bulk substrate retained by the thinner substrate, wherein each voltage pulse of the ECDM process comprises: an initial higher voltage period during which gas bubbles are formed in the low-conductive electrolyte and yield a localized dielectric region in the low-conductive electrolyte; and a subsequent lower voltage period during which a plasma built up in the localized dielectric region formed by the gas bubbles causes electrical discharge machining of the beveled edge of the thicker bulk substrate retained by the thinner substrate. The tool electrode may be tilted during the ECDM process to change an angle of the beveled edge of the thicker bulk substrate retained by the thinner substrate and/or to change the shape of the beveled edge of the thicker bulk substrate retained by the thinner substrate. Alternatively, the tool electrode may be moved only in a vertical direction during the ECDM process so that an angle of the beveled edge of the thicker bulk substrate retained by the thinner substrate remains unchanged by the EDM process. Separately or in combination, the method may further comprise tilting a tool electrode used to process the part of the beveled edge of the thicker bulk substrate retained by the thinner substrate as part of the EDM process and/or the ECDM process, to change an angle of the beveled edge of the thicker bulk substrate retained by the thinner substrate and/or to change the shape of the beveled edge of the thicker bulk substrate retained by the thinner substrate. Separately or in combination, the method may further comprise: producing an additional thinner substrate from the thicker bulk substrate; and processing an edge of the additional thinner using the EDM process and/or the ECDM process. The additional thinner substrate may retain no part of the beveled edge of the thicker bulk substrate. The method may further comprise tilting a tool electrode used to process the edge of the additional thinner substrate as part of the EDM process and/or the ECDM process, to bevel the edge of the additional thinner substrate. Alternatively, the method may further comprise moving a tool electrode used to process the edge of the additional thinner substrate as part of the EDM process and/or the ECDM process only in a vertical direction, so that an angle of the edge of the additional thinner substrate remains unchanged by the EDM process and/or the ECDM process.

Separately or in combination, the part of the beveled edge of the thicker bulk substrate retained by the thinner substrate may be processed using the EDM process and/or the ECDM process before separating the thinner substrate from the thicker bulk substrate.

Separately or in combination, the part of the beveled edge of the thicker bulk substrate retained by the thinner substrate may be processed using the EDM process and/or the ECDM process before a metallization is formed on a front main surface of the thinner substrate.

Separately or in combination, the thicker bulk substrate may be a SiC wafer.

Separately or in combination, the thicker bulk substrate may be a GaN wafer.

Separately or in combination, the device substrate may have a thickness less than 150 μm after being separated from the thicker bulk substrate.

Separately or in combination, the device substrate may retain only part of the beveled edge of the thicker bulk substrate after being separated from the thicker bulk substrate.

Separately or in combination, the method may further comprise tilting a tool electrode used to process the edge of the device substrate as part of the EDM process and/or the ECDM process, to add an angled face to the edge of the device substrate.

According to another embodiment of a method, the method comprises: producing a bulk substrate; and beveling an edge of the semiconductor substrate using an electrical discharge machining (EDM) process and/or an electrochemical discharge machining (ECDM) process.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1A illustrates a cross-sectional view of a bulk substrate prior to thinning, and

FIG. 1B illustrates the bulk substrate post thinning.

FIGS. 2A through 2D illustrate respective cross-sectional views of an embodiment of processing the edge of a thinner substrate produced from a thicker bulk substrate, during different stages of processing.

FIGS. 3A and 3B illustrate the section of the bulk substrate within the dashed box in FIG. 2B, during different stages of an electrical discharge machining (EDM) process.

FIGS. 4A and 4B illustrate the section of the bulk substrate within the dashed box in FIG. 2B, during different stages of an electrochemical discharge machining (ECDM) process.

FIGS. 5 through 7 illustrate respective perspective vies of different embodiments of an EDM/ECDM tool electrode used to process the edge of a thinner substrate produced from a thicker bulk substrate.

FIGS. 8A through 8E illustrate respective cross-sectional views during different stages of an embodiment in which a thinner substrate separated from a thicker bulk substrate retains at least part of the original beveled edge of the bulk substrate using an EDM and/or ECDM process.

FIGS. 9A through 9F illustrate respective cross-sectional views during different stages of an embodiment in which the edge of multiple thinner substrates produced from the same bulk substrate are processed by EDM and/or ECDM.

FIGS. 10A through 10F illustrate respective cross-sectional views during different stages of another embodiment in which the edge of multiple thinner substrates produced from the same bulk substrate are processed by EDM and/or ECDM.

### DETAILED DESCRIPTION

The embodiments described herein provide a technique for processing the edge of a thinner substrate produced from a thicker bulk substrate. The thicker bulk substrate may be a semiconductor wafer, a glass wafer, a ceramic wafer, etc. In the case of a semiconductor wafer, the thinner wafer produced from the thicker wafer may be a device wafer which includes one or more activate and/or passive electrical devices. The thinner substrate may be produced from the thicker substrate by separating or cutting the thinner substrate from the bulk substrate, by thinning the backside of the bulk substrate, e.g. by grinding, etc. The edge processing embodiments described herein may be applied to any type of substrate including silicon wafers and semiconductor wafers having a hardness greater than that of silicon, e.g., SiC wafers, GaN wafers, etc., glass substrates, ceramic substrates, etc. The edge processing embodiments described herein allow for reshaping of the edge of a thinner substrate produced from a thicker bulk substrate without the thinner substrate having sharp edges. Hence, the edge processing embodiments described herein avoid challenges associated with handling semiconductor wafers having sharp edges and also mitigate against wafer breakage caused by hairline cracks which propagate from sharp edges of a thinned semiconductor wafer. In addition or as an alternative, edge processing embodiments described herein may be used for creating and/or for re-defining an alignment mark of the substrate. The alignment mark may, for example, be a straight part of the edge of the substrate (so-called wafer flat) or a notch (so-called wafer notch) at an edge of the substrate. The edge processing embodiments described herein are performed using an electrical discharge machining (EDM) process, an electrochemical discharge machining (ECDM) process or a combination of EDM and ECDM. The EDM and ECDM processes are described in more detail later herein. It should be understood that any of the embodiments described herein may use EDM exclusively for edge processing, ECDM exclusively for edge processing, or a combination of EDM and ECDM for edge processing.

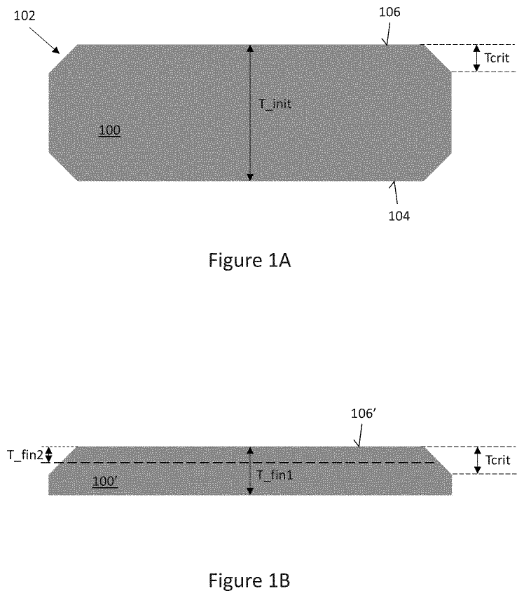

FIG. 1A illustrates a cross-sectional view of a bulk substrate 100. Any type of substrate having an edge 102 in need of processing may be used. For example, the bulk substrate 100 may be a monocrystalline Si wafer. In other cases, the bulk substrate 100 may be a bulk semiconductor wafer having a hardness less than Si, e.g. a Ge wafer, a GaAs wafer, etc. In other cases of bulk semiconductor wafers, the bulk substrate 100 may have a hardness greater than Si, e.g. a GaN wafer, a SiC wafer, etc. In still other cases, the bulk substrate 100 may be a glass substrate, a ceramic substrate, etc. In a specific embodiment, the bulk substrate 100 is a monocrystalline 4H-SiC wafer. In the case of a bulk semiconductor wafer, the bulk substrate 100 may be doped or undoped. In the case of a doped wafer, the conductivity of the bulk semiconductor substrate 100 may be greater than 0.01 Siemens(S)/cm (or a resistivity of less than 100 ωcm) in some embodiments.

In each case, the bulk substrate 100 has a beveled edge 102 which circumscribes the perimeter of the substrate 100. In the case of a bulk semiconductor wafer, no functional devices will be formed in the peripheral region of the bulk substrate 100 which includes the beveled edge 102. The bulk substrate 100 has an initial (starting) thickness T_init measured between the bottom and top sides 104, 106 of the bulk substrate 100. The beveled edge 102 of the bulk substrate 100 has a thickness of T_crit at the top side 106 of the bulk substrate 100 and which is less than T_init.

FIG. 1B illustrates the bulk substrate 100 after thinning at the backside 104 to a thickness of T_fin1>T_crit. Because T_fin1 is greater than the thickness T_crit of the beveled edge 102, the thinning process did not extend into the beveled edge 102 at the top side 106 of the bulk substrate 100 and thus the shape of the beveled edge 102 remains unchanged for a thinner substrate 100′ produced from the thicker bulk substrate 100. However, a thinner substrate may be needed or desired. Further thinning of the bulk substrate 100 to a thickness of T_fin2<T_crit will change the shape of the beveled edge 100 at the top side 106′ of the thinner substrate 100′ produced from the bulk substrate 100 and result in sharp edges which can lead to wafer handling issues and/or wafer breakage in the case of semiconductor wafers.

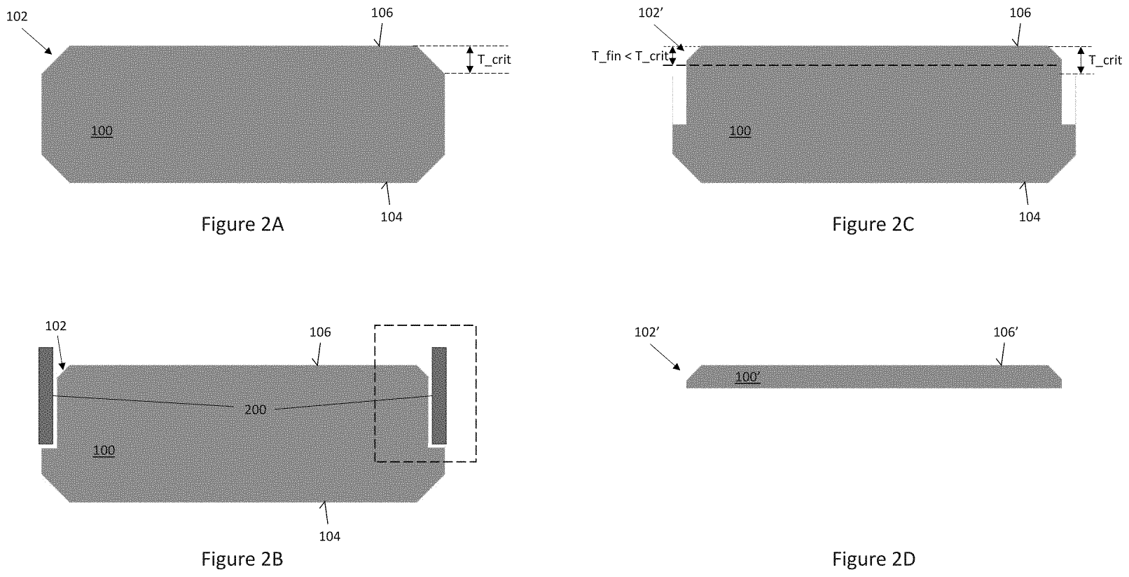

FIGS. 2A through 2D illustrate an embodiment of processing the edge 102 of the bulk substrate 100 so that the bulk substrate 100 may be thinned to less than the thickness T_crit of the edge 102 at the top side 104 of the bulk substrate 100, but without forming sharp edges. The thinner substrate 100′ produced from the bulk substrate 100 may be used for device fabrication, in the case of a bulk semiconductor substrate. For example, logic devices, power devices, passive devices, etc. may be fabricated using the thinner substrate 100′ produced from the bulk substrate 100. The devices are included in dies (chips) which are singulated after device processing is complete. Device processing is well known in the semiconductor art, and thus no further explanation of such processing is provided herein.

FIG. 2A shows the bulk substrate 100 from FIG. 1A. The bulk substrate 100 has an initial (starting) thickness T_init measured between the bottom and top sides 104, 106 of the bulk substrate 100. The beveled edge 102 of the bulk substrate 100 has a thickness of T_crit<T_init at the top side 106 of the bulk substrate 100.

FIG. 2B shows the bulk substrate 100 during processing of the substrate edge 102. The angle and/or the shape of the part 102′ of the original beveled edge 102 of the bulk substrate 100 to be retained by the thinner semiconductor substrate 100′ produced from the bulk substrate 100 is changed by the processing. The original beveled edge 102 of the bulk substrate 100 is processed using an EDM process and/or an ECDM process to re-angle and/or re-shape the part 102′ of the original beveled edge 102 of the bulk substrate 100 to be retained by the thinner substrate 100′.

FIG. 2C shows the bulk substrate 100 after the edge processing. According to this embodiment, the thinned substrate 100′ produced from the bulk substrate 100 retains only part 102′ of the original beveled edge 102 of the thicker bulk substrate 100.

FIG. 2D shows the resulting thinner substrate 100′ produced from the thicker bulk substrate 100. The thinner substrate 100′ may be produced from the thicker bulk substrate 100 using a standard process such as splitting, cutting, thinning by grinding, etc., or a combination of at least two of standard processes (e.g., splitting followed by grinding and/or splitting followed by thinning or vice-versa). The thinner substrate 100′ retains at least part 102′ of the original beveled edge 102 of the bulk substrate 100 according to this embodiment. By processing the beveled edge 102 of the bulk substrate by EDM and/or ECDM, the beveled edge 102′ of the thinner substrate 100′ produced from the thicker bulk substrate 100 can be angled and/or shaped such that the thickness T_fin of the thinned substrate 100 may be less than the thickness T_crit of the original beveled edge 102 of the bulk substrate 100 without yielding sharp edges.

FIG. 2B shows the substrate edge processing being performed by an EDM/ECDM electrode 200 before the thinner substrate 100′ is separated from the thicker bulk substrate 100. However, the thinner substrate 100′ instead may be separated from the thicker bulk substrate 100 before the substrate edge processing is performed. For example, the bulk substrate 100 may be partly or completely thinned to a final thickness T_fin before the substrate edge processing is performed. Hence, the bulk substrate 100 may be completely thinned, partly thinned or not thinned at all when the substrate edge 102 is re-beveled using EDM and/or ECDM. While the resulting re-beveled edge 102′ is shown as a straight line in the figures for ease of illustration, in reality the re-beveled edge 102′ realized by the EDM and ECDM processes described herein may have some curvature.

Additional processing may be done to the bulk substrate 100 before or after the substrate edge processing is performed. For example, in the case of semiconductor wafers, an epitaxial layer (not shown) may be grown on the bulk substrate 100 before or after processing the substrate edge 102. Separately or in combination, the part 102′ of the original beveled edge 102 of the bulk substrate 100 retained by the thinner substrate 100′ may be processed using EDM and/or ECDM before a metallization is formed on the top side 106′ of the thinner substrate 100′. The original beveled edge of the bulk substrate 100 may be formed using the EDM process and/or the ECDM process described herein.

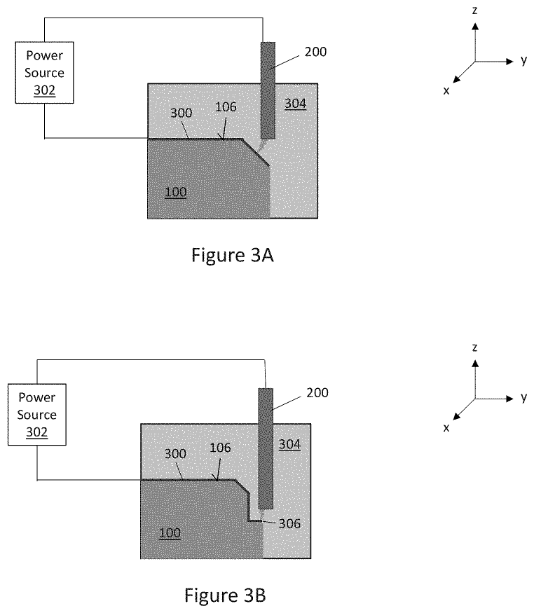

FIGS. 3A and 3B illustrate the section of the bulk substrate 100 within the dashed box in FIG. 2B, during different stages of the substrate edge processing implemented by EDM. EDM machines/removes semiconductor material by sublimation, melting, decomposition and/or spalling. In some embodiments, an assisting electrode (AE) 300 may be formed at the side 106 of the bulk semiconductor substrate 100 to be machined by the EDM process. The assisting electrode 300 may have a sufficient electrical conductivity to prevent substantial current from flowing through the bulk semiconductor substrate 100 to the opposite side 104 (out of view in FIGS. 3A and 3B) during the EDM process, e.g., in the case of a glass or ceramic bulk substrate 100. The assisting electrode 300 can, however, be dispensed with in other embodiments such as in the case of a bulk semiconductor substrate 100. For example, a SiC, Si or GaN bulk wafer 100 would not require the assisting electrode 300 since such types of semiconductor wafers have sufficient conductivity to function as an electrode. In one embodiment, the assisting electrode 300 is deposited on the side 106 of the bulk substrate 100 to be machined by the EDM process. For example, a carbon layer may be screen printed or deposited on the bulk substrate 100 to form the assisting electrode 300. In a more specific embodiment, a carbon-based lacquer may be screen printed onto the bulk substrate 100 and dried to form the assisting electrode 300. In another embodiment, the assisting electrode 300 is a highly doped region formed at the side 106 of the bulk substrate 100 in the case of a semiconductor wafer.

A tool electrode 200 is positioned near the part of the substrate edge 102 to be machined by the EDM process. A power source 302 applies voltage pulses between the assisting electrode 300 and the tool electrode 200, or directly between the bulk substrate 100 and the tool electrode, as part of the EDM process. No direct physical contact occurs between the tool electrode 200 and the bulk substrate 100. Hence, the EDM process may be used to machine/remove semiconductor material much harder than the tool electrode 200, e.g. such as SiC. The EDM process machines/removes material in the region of the beveled substrate edge 102 by sublimation, melting, decomposition and/or spalling.

A dielectric liquid 304 such as an oil-based or water-based dielectric may be used to aid in machining the beveled edge 102 of the bulk substrate 100 regardless of its conductivity. The dielectric liquid 304 covers the part of the beveled edge 102 to be machined by the EDM process. In one embodiment, the dielectric liquid 304 may completely cover the side 106 of the bulk substrate 100 to be machined by the EDM process. During the EDM process, the tool electrode 200 and/or the bulk substrate 100 may be moved in the dielectric liquid 304, e.g., in the vertical direction (z) so that the tool electrode 200 remains in close proximity to the beveled edge 102 of the bulk substrate 100 to maintain a plasma between the tool electrode 200 and the bulk substrate 100. In addition or alternatively, the plasma may be maintained by increasing the applied voltage.

The initial discharge, which is graphically illustrated in FIG. 3A as a spark/bolt, may take place between the tool electrode 200 and the assisting electrode 300 formed at the side 106 of the bulk substrate 100 to be machined by the EDM process, or directly between the bulk substrate 100 and the tool electrode 200 if the assisting electrode 300 is omitted. The voltage and frequency of the pulses applied by the power source 302 are sufficient to free metal ions from the assisting electrode 300 in a region of the assisting electrode 300 positioned in close proximity to the tool electrode 200, or to free material directly from the bulk substrate 100 if the assisting electrode 300 is omitted.

If an oil-based dielectric 304 is used, the plasma produced during sparking may crack the oil-based dielectric liquid 304 and form a pyrostatic carbon. The pyrostatic carbon, if present, deposits on the exposed beveled edge 102 of the bulk substrate 100. The deposited pyrostatic carbon may form an intrinsic conductive layer 306 on the beveled edge 102 of the bulk substrate 100 being processed by EDM, as shown in FIG. 3B. The intrinsic conductive layer 306 provides electrical conductivity which allows for continued processing of the beveled edge 102 of the bulk substrate 100 with successive sparks (shown as a spark/bolt in FIG. 3B) caused by voltage pulses applied by the power source 302 between the tool electrode 200 and the intrinsic conductive layer 306 formed on the beveled edge 102 of the bulk substrate 100. As a result, material such as ions and/or chunks of substrate material are removed from the beveled edge 102 of the bulk substrate 102 during the EDM process. In one embodiment, the pulse energy (Voltage*Current*Pulse-On-Time) per voltage pulse is at most 1 milli-joule during the EDM process. If a water-based or other type of non-oil-based dielectric is used, neither pyrostatic carbon nor the intrinsic conductive layer 306 is formed.

In either case, with every additional spark, a part of the substrate beveled edge 102 is removed. By using EDM, a bulk substrate 100 with very high hardness such as, for example, a SiC wafer, a GaN wafer, a glass substrate, a ceramic substrate, etc. may be machined. If the bulk substrate 100 has poor electrical conductivity, the assisting electrode 300 may be used. The intrinsic conductive layer 306, if present, may be removed at the end of the EDM process. For example, the intrinsic conductive layer 306 may be removed by an oven process and/or by use of an oxygen-rich plasma, e.g., which may include O₃ (ozone). The EDM process continues until the beveled edge 102 of the bulk substrate 100 is re-shaped and/or re-angled as desired so that the thinning of the bulk substrate 100 to the final target thickness T_fin (e.g., less than 150 μm, e.g., 40 to 150 μm, e.g. 40 to 100 μm e.g., 10 to 40 μm, e.g., 10 to 40 μm) does not extend into the redefined beveled edge 102′ of the thinner substrate 100′ produced from the bulk substrate 100. Again, the thinner substrate 100′ may be separated from the thicker bulk substrate 100 before or after the EDM process. In either case, the thinner substrate 100′ retains at least part 102′ of the original beveled edge 102 of the bulk substrate 100 after the EDM process is complete according to this embodiment.

The open source voltage applied by the power source 302 during the EDM process can range from 14 V to 200 V, for example. The current of the pulses applied by the power source 302 can range from 0.1 to 100 Amperes, for example. The duration of the pulses may be varied as desired, as may be the off time between pulses. The EDM process may be stopped one or more times during the beveled edge machining process, for example for several seconds at a time, to allow replacement of dirty dielectric liquid with new dielectric liquid. The EDM tool can automatically trim the tool electrode 200 during the EDM process, to maintain tool electrode integrity. When a pulse starts to take place, the diameter of the resulting plasma region formed between the tool electrode 200 and the bulk substrate 100 depends on the pulse on time. The duration of the pulses may be selected to control the degree or localization of the plasma created by the EDM process. For a large pulse duration, the plasma may be bigger. In the microsecond EDM range, the plasma diameter is smaller and hence the amount of joule heating may be relatively small and a small localized region of the bulk substrate 100 is affected.

In one embodiment, the voltage pulses are applied by the power source 302 for periods of at most 12 microseconds as part of the EDM process. This embodiment is also referred to herein as μ-EDM, owing to the micro-second pulse duration. As used herein, ‘EDM’ is a term intended to broadly mean electrical discharge machining and includes the case where the pulse energy (Voltage*Current*Pulse-On-Time) per pulse is at most 1 mili joules (μ-EDM) and the case where the energy per pulse is greater than 1 mili joules. However, μ-EDM may yield a smoother (less rough) surface with less thickness variation and less likelihood of wafer cracking in the case of a semiconductor wafer as the bulk substrate 100.

In one embodiment, the voltage pulses are applied by the power source 302 with pulse energy per pulse greater than 1 mili joules during a first part of the EDM process and with pulse energy per pulse less than 1 mili joules during a second part of the EDM process after the first part. According to this embodiment, most of the beveled edge machining is achieved during the first part of the EDM process, with the second part of the μ-EDM process yielding a relatively smooth final beveled edge surface with less thickness variation.

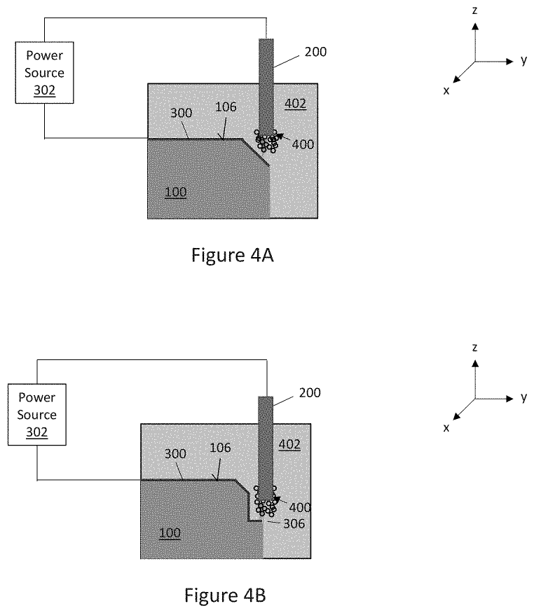

FIGS. 4A and 4B illustrate the section of the bulk substrate 100 within the dashed box in FIG. 2B, during different stages of the substrate edge processing implemented by ECDM. ECDM involves both spark erosion and anodic dissolution. Anodic dissolution occurs during an electrochemical machining (ECM) phase of the ECDM process characterized by high voltage and high current, and spark erosion occurs during an EDM phase of the ECDM process during which the voltage and current drop. During the ECM phase, there is no sparking and gas bubbles 400 such as H2, water vapor or oxygen are formed around the tool electrode 200. The gas bubbles 400 act like a localized dielectric, which facilitates the subsequent sparking/EDM phase of the ECDM process. Instead of a dielectric, a low-conductive electrolyte 402 such as NaClO₃, diluted HCl, NaOH/KOH/NaCl, etc. covers the part of the beveled edge 102 of the bulk substrate 100 to be machined by the ECDM process.

The electrolyte 402 breaks down during the ECM phase of the ECDM process to form the gas bubbles 400. The power source 302 applies voltage pulses and the assisting electrode 300 may or may not be provided, as explained above. Each voltage pulse of the ECDM process includes: an initial higher voltage period (the ECM phase) during which gas bubbles 400 are formed in the low-conductive electrolyte 402 and yield a localized dielectric region in the low-conductive electrolyte 402; and a subsequent lower voltage period (the EDM phase) during which a plasma built up in the localized dielectric region formed by the gas bubbles 400 and which causes electrical discharge machining of the substrate beveled edge 102.

In the EDM process illustrated in FIGS. 3A and 3B, a high voltage builds up with no current to form a plasma. Once the plasma channel is formed, current flows and the plasma melts the tool electrode 200 and the assisting electrode 300, if used. By turning off the plasma, the gas bubbles formed in the dielectric liquid implode, causing removal of melted/heated parts. In the ECDM process illustrated in FIGS. 4A and 4B, when the high voltage is applied by the power source 302, some current is already flowing (e.g. 1 or 2 amperes). Hence, ECM occurs during this phase of the ECDM process until a plasma builds up.

When the plasma builds up, the voltage decreases and the current increases due to localized sparking. The beveled edge 102 of the bulk substrate 100 is thus processed/machined during both the ECM phase (by anodic dissolution) and the EDM phase (by spark erosion) of the ECDM process. ECDM compared to just EDM without ECM reduces the amount of erosion of the tool electrode 200, since the tool electrode 200 is protected by gas bubbles 400. Also, ECDM imparts lower residual stress and the ECM chemistry reduces adverse thermal effects.

Described next are various embodiments of the EDM/ECDM tool electrode 200 used to implement the EDM and ECDM processes described above. The tool electrode embodiments described next may be used to re-shape and/or re-angle the beveled edge 102 of a bulk substrate 100 exclusively by EDM, exclusively by ECDM or by a combination of both EDM and ECDM.

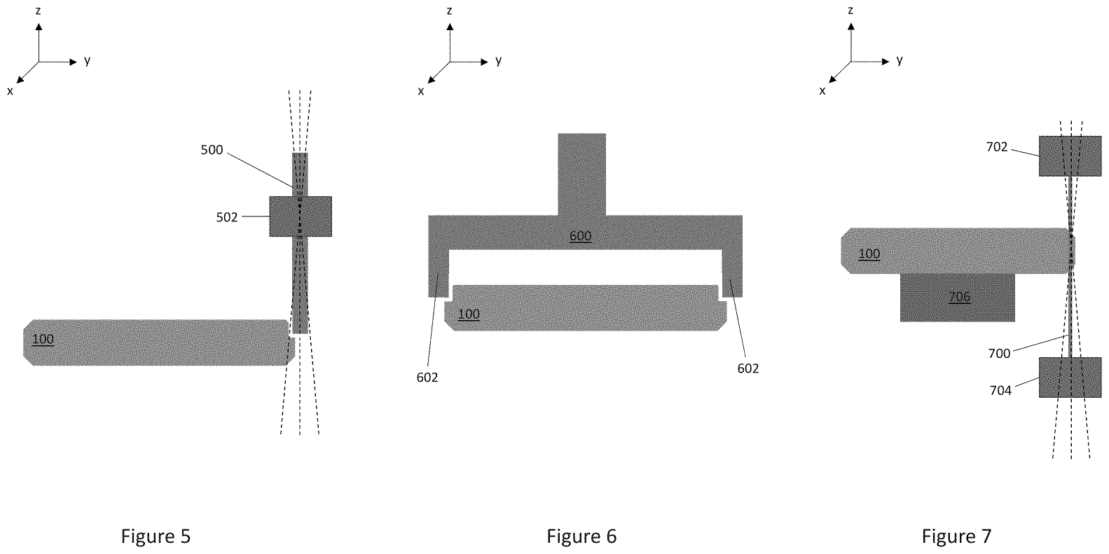

FIG. 5 illustrates an embodiment of the EDM/ECDM tool electrode 200 used to process/machine the beveled edge 102 of a bulk substrate 100 before or after separating a thinner substrate 100′ from the thicker bulk substrate 100, so that the thinner substrate 100′ produced from the bulk substrate 100 retains at least part 102′ of the original beveled edge 102 of the bulk substrate 100 and does not have sharp edges. According to this embodiment, the EDM/ECDM tool electrode 200 is a single rod 500 used for precise μ-EDM milling. The bulk substrate 100 to be processed/machined by EDM and/or ECDM rotates around the single rod 500 and/or the single rod 500 rotates around the bulk substrate 100. A tool head 502 to which the rod 500 is secured may rotate in multiple directions so that the rod 500 can be tilted along one or more different axes during the EDM and/or ECDM process as indicated by the dashed lines in FIG. 5, to change the angle and/or shape of the beveled edge 102′ retained by the thinner substrate 100′. The tool head 502 extends the rod 500 downward from the top of the tool head 500 toward the bulk substrate 100 being machined, to maintain a suitable distance between the rod 500 and the bulk substrate 100 as the rod 500 erodes down during the EDM and/or ECDM process.

FIG. 6 illustrates another embodiment of the EDM/ECDM tool electrode 200 used to process/machine the beveled edge 102 of a bulk substrate 100 before or after separating a thinner substrate 100′ from the thicker bulk substrate 100, so that the thinner substrate 100′ retains at least part 102′ of the original beveled edge 102 of the bulk substrate 100 and does not have sharp edges. According to this embodiment, the EDM/ECDM tool electrode 200 is a fork-shaped electrode 600 with two or more tine-like electrodes 602 used for machining by sinking. The bulk substrate 100 and/or the fork-shaped electrode 600 rotates. The fork-shaped electrode 600 does not tilt. Hence, the fork-shaped electrode 600 is moved only in a vertical direction (z) to maintain the plasma and so that the angle and/or shape of the beveled edge 102′ retained by the thinner substrate 100′ produced from the bulk substrate 100 remains unchanged by the EDM and/or ECDM process. The fork-shaped electrode 600 may be lowered toward the bulk substrate 100 being machined to maintain a suitable distance between the fork-shaped electrode 600 and the bulk substrate 100 as the fork-shaped electrode 600 erodes during the EDM and/or ECDM process. The original bevel 102 of the bulk substrate 100 is present on the first thinner substrate 100′ produced from the bulk substrate 100, but not on additional thinner substrates produced from the same bulk substrate 100 by using the fork-shaped tool electrode 600 shown in FIG. 6. Instead, each subsequent thinner substrate yielded from the bulk substrate 100 have a rectangular edge/no bevel. The edges of each subsequently produced thinner substrate may be subsequently processed to add a bevel.

FIG. 7 illustrates another embodiment of the EDM/ECDM tool electrode 200 used to process/machine the beveled edge 102 of a bulk substrate 100 before or after separating a thinner semiconductor substrate 100′ from the thicker bulk semiconductor substrate 100, so that the thinner substrate 100′ retains at least part 102′ of the original beveled edge 102 of the bulk substrate 100 and does not have sharp edges. According to this embodiment, the EDM/ECDM tool electrode 200 is a wire (foil) electrode 700 and the EDM and/or ECDM process is a wire EDM (WEDM) or wire ECDM (WECDM) process. The wire electrode 700 may be wound between two spools 702, 704 so that the active part of the wire electrode 700 used for machining the bulk substrate 100 changes. The bulk substrate 100 itself or the optional assisting electrode 300 applied to the bulk substrate 100 forms the other electrode. The power source 302 applies voltage pulses between the wire electrode 700 and the other electrode as previously described herein with an EDM and/or ECDM process. The power source 302 is not shown in FIG. 7 for ease of illustration, but is illustrated in FIGS. 3A-3B and 4A-4B.

The bulk substrate 100 may be supported only in the middle, e.g., by a chuck 706. The wire electrode 700 is feed in from the side, and the wire electrode 700 and/or the bulk substrate 100 is rotated. The wire electrode 700 may be titled along one or more different axes during the EDM and/or ECDM process as indicated by the dashed lines in FIG. 7, to change the angle and/or shape of the beveled edge 102′ retained by the thinner substrate 100′ produced from the bulk substrate 100. The bulk substrate 100 may be thinned before the wire electrode 700 is used to process the beveled edge 102.

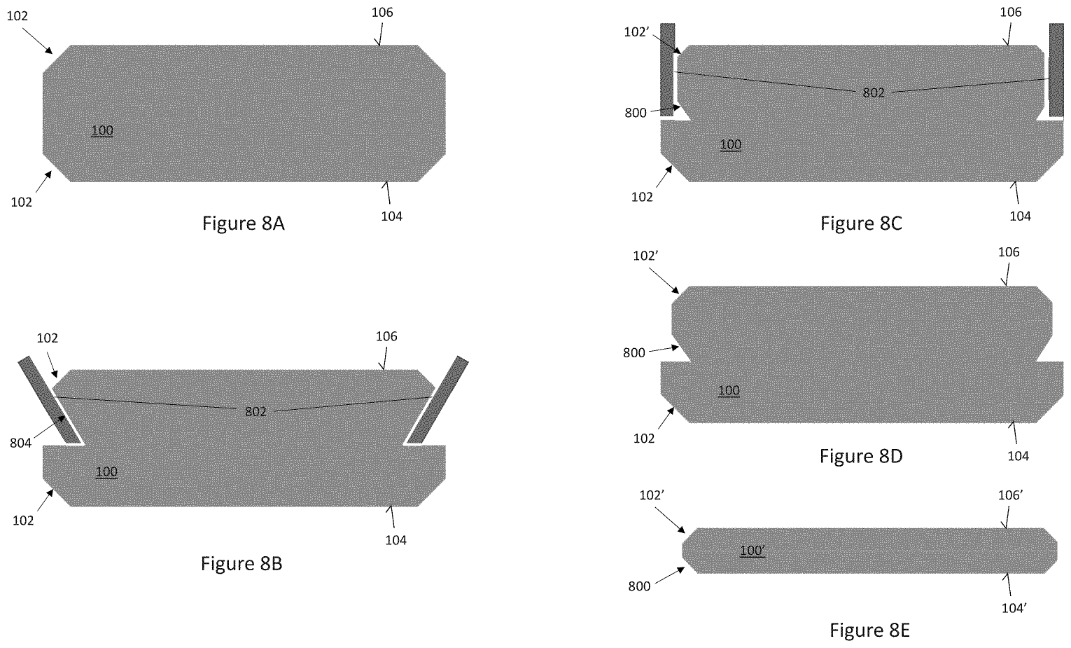

FIGS. 8A through 8E illustrate an embodiment in which a thinner substrate 100′ produced from a thicker bulk substrate 100 retains at least part 102′ of the original beveled edge 102 of the bulk substrate 100, and in which the bottom side 104′ of the thinner substrate 100′ is also processed by EDM and/or ECDM so as to have a beveled edge 800 at both sides 104′, 106′ of the thinned substrate 100′.

FIG. 8A shows the bulk substrate 100 prior to processing by EDM and/or ECDM. The bulk substrate 100 has a beveled edge 102 at the top and bottom sides 106, 104 of the bulk substrate 100.

FIG. 8B shows an EDM/ECDM tool electrode 802, e.g., of the kind previously described herein, processing the top side 106 of the bulk substrate 100 to create an inward slanting edge face 804 at the top side 106 of the bulk substrate 100. According to this embodiment, by tilting the EDM/ECDM tool electrode 800, an angled face 804 is added to the beveled edge 102′ retained by the thinner substrate 100′ produced formed from the thicker bulk substrate 100.

FIG. 8C shows the EDM/ECDM tool electrode 800 vertically processing the edge 102 of the bulk substrate 100, to complete the beveled edge 102′ at what will be the top side 106′ of the thinner substrate 100′ produced from the thicker bulk substrate and the beveled edge 800 at what will be the bottom side 104′ of the thinner substrate 100′.

FIG. 8D shows the bulk substrate 100 after processing by EDM and/or ECDM and prior to separating the thinner substrate 100′ from the thicker bulk substrate 100.

FIG. 8E shows the thinner substrate 100′ after separation from the thicker bulk substrate 100, e.g., by splitting, cutting, grinding, etc. The thinner substrate 100′ produced from the thicker bulk substrate 100 has a beveled edge 102′ at both the top side 106′ and a beveled edge 800 at the bottom side 104′ of the thinner substrate 100′. The bulk substrate 100 may be partly or completely thinned to the final target thickness and then processed by EDM and/or ECDM to form the beveled edges 102′, 800 at both sides 106′, 104′ of the thinner substrate 100.

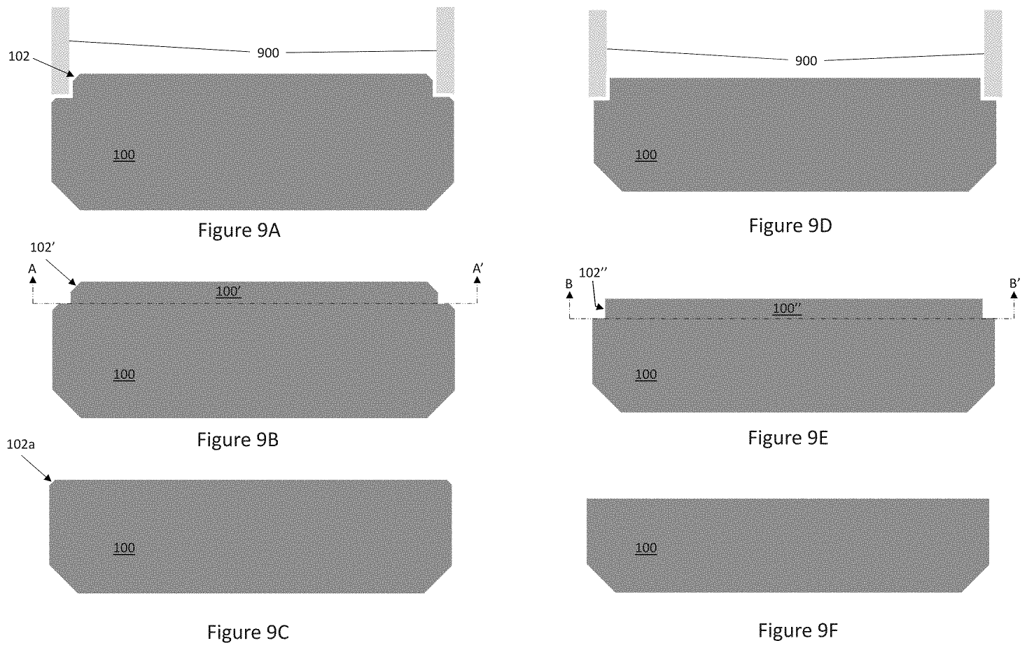

FIGS. 9A through 9F illustrate an embodiment in which multiple thinner substrates are serially produced from a thicker bulk substrate 100. According to this embodiment, only the first thinner substrate 100′ produced from the thicker bulk substrate 100 retains at least part of the original beveled edge 102 of the bulk substrate 100.

FIG. 9A shows processing the part 102′ of the beveled edge 102 of the bulk substrate 100 to be retained by the first thinner substrate 100′ using an EDM/ECDM tool electrode 900, e.g., of the kind previously described herein. The beveled edge 102 of the bulk substrate 100 may be processed by EDM and/or ECDM, also as previously described herein. The part 102′ of the original beveled edge 102 retained by the first thinner substrate 100′ produced from the bulk substrate 100 may be re-shaped and/or re-angled as previously described herein. The EDM and/or ECDM processing shown in FIG. 9A may be similar to that which is illustrated in FIG. 2B and previously described herein.

FIG. 9B shows the bulk substrate 100 after the EDM and/or ECDM processing and prior to separation of the first thinner substrate 100′ from the thicker bulk substrate 100 along the line labelled A-A′. As shown in FIG. 9B, the first thinner substrate 100′ retains at least part 102′ of the beveled edge 102 of the bulk substrate 100.

FIG. 9C shows the bulk substrate 100 after separation of the first thinner substrate 100′ from the bulk substrate 100, along the line labelled A-A′ in FIG. 9B. The first thinner substrate 100′ may be separated from the thicker bulk substrate 100 by, e.g., splitting, cutting, etc. The bulk substrate 100 may retain part 102a of the original beveled edge 102 as shown in FIG. 9C, or none of the original beveled edge 102.

FIG. 9D shows a subsequent processing of the edge of the remaining bulk substrate 100 using the EDM/ECDM tool electrode 900 to re-shape and/or re-angle the substrate edge. The EDM and/or ECDM processing employed in FIG. 9D may be similar to the EDM/ECDM processing performed in FIG. 9A.

FIG. 9E shows the bulk substrate 100 after the second EDM and/or ECDM processing and prior to separation of a second thinner substrate 100″ from the bulk substrate 100 along the line labelled B-B′.

FIG. 9F shows the bulk substrate 100 after separation of the second thinner substrate 100″ from the bulk substrate 100, along the line labelled B-B′ in FIG. 9E. The second thinner substrate 100″ may be separated from the thicker bulk substrate 100 by, e.g., splitting, cutting, etc. According to this embodiment, the second thinner substrate 100″ retains no part of the original beveled edge 102 of the bulk substrate 100 after separation from the bulk substrate 100.

However, the second thinner substrate 100″ may be further processed by EDM and/or ECDM as described earlier herein to bevel the edge 102″ of the second thinner substrate 100″. For example, the EDM/ECDM tool electrode 900 used to process the edge 102″ of the second thinner substrate 100″ may be tilted as part of the EDM and/or ECDM process shown in FIG. 9D to bevel the edge 102″, e.g., as previously described herein in connection with FIGS. 5 and 7. Otherwise, the EDM/ECDM tool electrode 900 used to process the edge 102″ of the second thinner substrate 100″ may only move in the vertical direction so that the angle of the edge 102″ of the second thinner substrate 100″ remains unchanged by the EDM and/or ECDM process, e.g., as previously described herein in connection with FIG. 6.

The remaining bulk substrate 100 may be processed one or more additional times using an EDM and/or ECDM process to re-shape the substrate edge and yield one or more additional thinner substrates, e.g., by repeating the steps illustrated in FIGS. 9D through 9F.

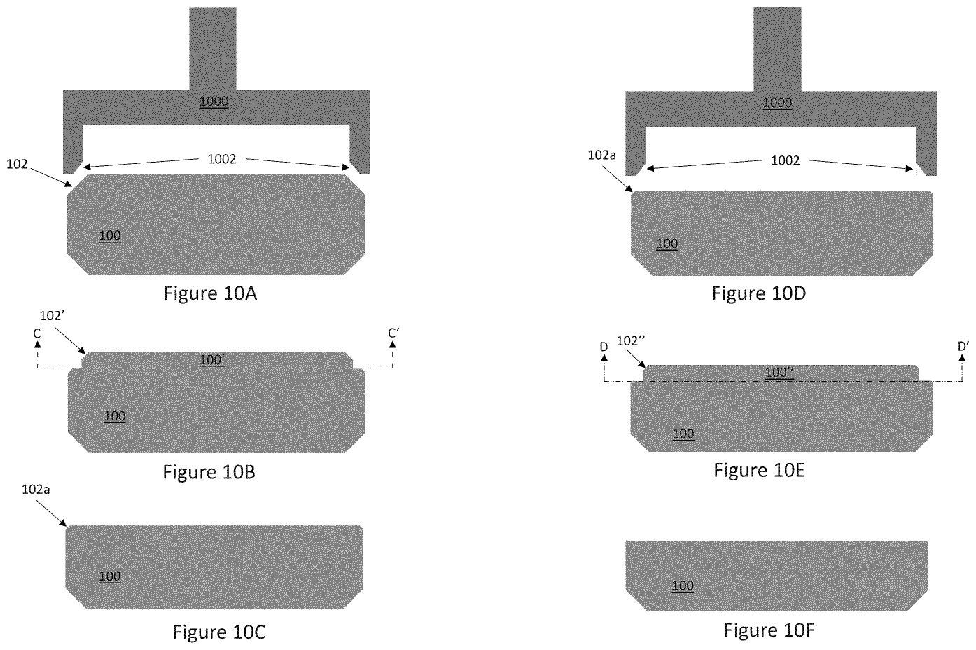

FIGS. 10A through 10F illustrate an embodiment in which multiple thinner substrates are serially produced from a thicker bulk substrate 100. According to this embodiment, each thinner substrate produced from the bulk substrate 100 has a beveled edge processed or formed by EDM and/or ECDM.

FIG. 10A shows processing the part 102′ of the original beveled edge 102 of the bulk substrate 100 to be retained by a first thinner substrate 100′ produced from the bulk substrate 100 using an EDM and/or ECDM process. The edge 102′ of the first thinner substrate 100 may be re-shaped and/or re-angled, as previously described herein. The EDM and/or ECDM processing shown in FIG. 10A may be similar to that which is illustrated in FIG. 9A. Different, however, the EDM/ECDM tool electrode 1000 has a beveled end 1002. The shape of the beveled end 1002 of the EDM/ECDM tool electrode 100 transfers to the edge 102 of the bulk substrate 100 during processing.

FIG. 10B shows the bulk substrate 100 after the EDM and/or ECDM processing and prior to separation of the first thinner substrate 100′ from the bulk substrate 100. As shown in FIG. 10B, the first thinner substrate 100′ retains at least part 102′ of the original beveled edge 102 of the bulk substrate 100.

FIG. 10C shows the bulk substrate 100 after separation of the first thinner substrate 100′ from the bulk substrate 100, along the line labelled C-C′ in FIG. 10B. The first thinner substrate 100′ may be separated from the thicker bulk substrate 100 by, e.g., splitting, cutting, etc. The bulk substrate 100 may retain part 102a of the original beveled edge 102 as shown in FIG. 100, or none of the original beveled edge 102.

FIG. 10D shows a subsequent processing of the edge of the remaining bulk substrate 100 using an EDM and/or ECDM process to re-shape and/or re-angle the substrate edge. The EDM and/or ECDM processing shown in FIG. 10D may be similar to the EDM/ECDM processing performed in FIG. 9D. Different, however, the EDM/ECDM tool electrode 1000 has a beveled end 1002 as described above. Hence, the shape of the beveled end 1002 of the EDM/ECDM tool electrode 1000 transfers to the second thinner substrate 100″ produced from the bulk substrate 100.

FIG. 10E shows the bulk substrate 100 after the second instance of EDM and/or ECDM processing and prior to separation of the second thinner substrate 100″ from the bulk substrate 100. Again, the shape of the beveled end 1002 of the EDM/ECDM tool electrode 1000 has been transferred to the second thinner substrate 100″ produced from the bulk substrate 100. Hence, the second thinner substrate 100″ to be separated from the bulk substrate 100 also has a beveled edge 102″, unlike the case illustrated in FIG. 9E.

FIG. 10F shows the bulk substrate 100 after separation of the second thinner substrate 100″ from the bulk substrate 100, along the line labelled D-D′ in FIG. 10E. The second thinner substrate 100″ may be separated from the thicker bulk substrate 100 by, e.g., splitting, cutting, etc. According to this embodiment, the second thinner substrate 100″ retains no part of the original beveled edge 102 of the bulk substrate 100 after separation from the bulk substrate 100. However, the second thinner substrate 100″ does have a beveled edge 102″ due to the use of the EDM/ECDM tool electrode 1000 with the beveled end 1002. The remaining bulk substrate 100 may be processed one or more additional times using an EDM and/or ECDM process to re-shape the edge and yield one or more additional thinner substrates, e.g., by repeating the steps illustrated in FIGS. 10D through 10F.

In addition or instead of producing a beveled edge with any of the methods described herein, an alignment mark (for example, a wafer flat or a wafer notch) may be produced with at least one of the embodiments described above. For example, at least part of the substrate may be processed using an EDM and/or ECDM process to re-shape the edge such that the alignment mark is produced at the edge.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method, comprising:
producing a thinner substrate from a thicker bulk substrate; and
processing an edge of the thinner substrate using an electrical discharge machining (EDM) process and/or an electrochemical discharge machining (ECDM) process.

2. The method of claim 1, wherein the thicker bulk substrate has a beveled edge prior to producing the thinner substrate from the thicker bulk substrate, and wherein processing the edge of the thinner substrate using the EDM process and/or ECDM process comprises:
processing a part of the beveled edge of the thicker bulk substrate retained by the thinner substrate using the EDM process and/or ECDM process.

3. The method of claim 2, wherein processing the part of the beveled edge of the thicker bulk substrate retained by the thinner substrate using the EDM process comprises:
covering the part of the beveled edge of the thicker bulk substrate retained by the thinner semiconductor substrate with a dielectric liquid;
applying voltage pulses between a tool electrode and the part of the beveled edge of the thicker bulk substrate retained by the thinner substrate; and
moving the tool electrode and/or the thinner substrate in the dielectric liquid to maintain a plasma between the tool electrode and the thinner.

4. The method of claim 3, further comprising:
tilting the tool electrode along one or more different axes during the EDM process to change an angle of the beveled edge of the thicker bulk substrate retained by the thinner substrate and/or to change the shape of the beveled edge of the thicker bulk substrate retained by the thinner substrate.

5. The method of claim 3, wherein the tool electrode is moved only in a vertical direction to maintain the plasma and so that an angle of the beveled edge of the thicker bulk substrate retained by the thinner substrate remains unchanged by the EDM process.

6. The method of claim 2, wherein processing the part of the beveled edge of the thicker bulk substrate retained by the thinner substrate using the ECDM process comprises:
covering the part of the beveled edge of the thicker bulk substrate retained by the thinner substrate with a low-conductive electrolyte; and
applying voltage pulses between a tool electrode and the part of the beveled edge of the thicker bulk substrate retained by the thinner substrate,
wherein each voltage pulse of the ECDM process comprises:
an initial higher voltage period during which gas bubbles are formed in the low-conductive electrolyte and yield a localized dielectric region in the low-conductive electrolyte; and
a subsequent lower voltage period during which a plasma built up in the localized dielectric region formed by the gas bubbles causes electrical discharge machining of the beveled edge of the thicker bulk substrate retained by the thinner substrate.

7. The method of claim 6, further comprising:
tilting the tool electrode during the ECDM process to change an angle of the beveled edge of the thicker bulk substrate retained by the thinner substrate and/or to change the shape of the beveled edge of the thicker bulk substrate retained by the thinner substrate.

8. The method of claim 7, further comprising:
moving the tool electrode only in a vertical direction during the ECDM process so that an angle of the beveled edge of the thicker bulk substrate retained by the thinner substrate remains unchanged by the EDM process.

9. The method of claim 2, wherein processing the part of the beveled edge of the thicker bulk substrate retained by the thinner substrate using the EDM process and/or ECDM process comprises:
tilting a tool electrode used to process the part of the beveled edge of the thicker bulk substrate retained by the thinner substrate as part of the EDM process and/or the ECDM process, to change an angle of the beveled edge of the thicker bulk substrate retained by the thinner substrate and/or to change the shape of the beveled edge of the thicker bulk substrate retained by the thinner substrate.

10. The method of claim 1, further comprising:
producing an additional thinner substrate from the thicker bulk substrate; and
processing an edge of the additional thinner substrate using the EDM process and/or the ECDM process to re-shape the outer edge region.

11. The method of claim 10, wherein the thicker bulk substrate has a beveled edge prior to producing the thinner substrate from the thicker bulk substrate, and wherein the additional thinner substrate retains no part of the beveled edge of the thicker bulk substrate after being separated from the thicker bulk substrate.

12. The method of claim 11, further comprising:
tilting a tool electrode used to process the edge of the additional thinner substrate as part of the EDM process and/or the ECDM process, to bevel the edge of the additional thinner substrate.

13. The method of claim 11, further comprising:
moving a tool electrode used to process the edge of the additional thinner substrate as part of the EDM process and/or the ECDM process only in a vertical direction, so that an angle of the edge of the additional thinner substrate remains unchanged by the EDM process and/or the ECDM process.

14. The method of claim 1, wherein the edge of the thinner substrate produced from the thicker bulk substrate is processed using the EDM process and/or the ECDM process before the thinner substrate is separated from the thicker bulk substrate.

15. The method of claim 1, wherein the edge of the thinner substrate produced from the thicker bulk substrate is processed using the EDM process and/or the ECDM process before a metallization is formed on a front main surface of the thinner substrate.

16. The method of claim 1, wherein the thicker bulk substrate is a SiC wafer, a GaN wafer, a glass substrate or a ceramic substrate.

17. The method of claim 1, wherein the thinner substrate produced from the thicker bulk substrate has a thickness less than 150 μm after being separated from the thicker bulk substrate.

18. The method of claim 1, wherein the thicker bulk substrate has a beveled edge prior to producing the thinner substrate from the thicker bulk substrate, and wherein the thinner substrate produced from the thicker bulk substrate retains only part of the beveled edge of the thicker bulk substrate after being separated from the thicker bulk substrate.

19. The method of claim 1, further comprising:
tilting a tool electrode used to process the edge of the thinner substrate produced from the thicker bulk substrate as part of the EDM process and/or the ECDM process, to add an angled face to the edge of the thinner substrate.

20. A method, comprising:
producing a bulk substrate; and
beveling an edge of the bulk substrate using an electrical discharge machining (EDM) process and/or an electrochemical discharge machining (ECDM) process.
